(19) United States
(12) Patent Application Publication
(10) Pub. No.: US 2010/0244243 A1
(43) Pub. Date: Sep. 30, 2010

(54) SEMICONDUCTOR DEVICE

(75) Inventor: Fumihiko Eya, Kanagawa-ken (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/703,936

(22) Filed: Feb. 11, 2010

(30) Foreign Application Priority Data
Mar. 24, 2009 (JP) 2009-072891

(51) Int. Cl. H01L 23/49; H01L 23/34

(52) U.S. Cl. 257/737; 257/E23.08; 257/E23.024

(57) ABSTRACT

A semiconductor device has a flexible substrate which can be folded U-shape, and an outer surface of the flexible substrate being provided concave-convex portions for heat radiation. The semiconductor device also has a semiconductor chip which is mounted on an inner surface of the flexible substrate, and the chip being electronically connected with the flexible substrate.

### CROSS REFERENCE TO RELATED APPLICATION

This application based upon and claims the benefit of priority from the prior Japanese Patent Application No. 2009-072891, filed on Mar. 24, 2009; the entire contents of which are incorporated herein by reference.

### FIELD OF THE INVENTION

The present invention relates to a semiconductor device.

### BACKGROUND OF THE INVENTION

Electronic components such as semiconductor chips involved in an electric equipment such as mobile communication devices and television receivers, are downsized for reduction in size. Mounting spaces of the electronic components are also restricted in the electric equipment. Components in a display device such as LCD (liquid crystal display) monitors and LCD televisions, are mounted on a substrate by COF (chip on film) method and a TAB (tape automated bonding) method. Japanese Patent Application Publication (Kokai) No. 2006-135247, for example, discloses that a pixel driver is mounted on a flexible substrate by the COF method. A package of the pixel driver can be thinner using the COF method and the flexible substrate, since the flexible substrate can be easily folded.

Recently, the display device becomes lager and finer, the pixel driver has multi-output. Heat radiation of the display device increases because power consumption per one pixel driver increases. The pixel driver is mounted on the folded flexible substrate in the display device using the COF method so that a exit of heat is blocked and preventing radiation. Heat radiation efficiency is drastically down and the display device is filled with heat.

### SUMMARY OF THE INVENTION

According to a first aspect of the present invention, a semiconductor device is provided, which comprises a flexible substrate which can be folded U-shape, an outer surface of the flexible substrate being provided concave-convex portions for heat radiation and a semiconductor chip which is mounted on an inner surface of the flexible substrate, the chip being electronically connected with the flexible substrate.

According to another aspect of the present invention, a semiconductor device is provided, which comprises a flexible substrate which can be folded U-shape, the flexible substrate being provided through holes for heat radiation and a semiconductor chip which is mounted on an inner surface of the flexible substrate, the chip being electronically connected with the flexible substrate.

### BRIEF DESCRIPTION OF THE DRAWINGS

FIG. 1 is a cross-sectional view showing a liquid crystal display device of a first embodiment according to the present invention.

FIG. 2 is an enlarged cross-sectional view showing a liquid crystal driver of the first embodiment.

FIG. 3 is a comparative example showing a portion of a driver of the first embodiment.

FIG. 4 is a cross-sectional view showing a liquid crystal driver of a second embodiment.

FIG. 5 is a cross-sectional view showing a liquid crystal display device of a third embodiment.

FIG. 6 is an enlarged cross-sectional view showing a region A of FIG. 5.

FIG. 7 is an enlarged cross-sectional view showing the liquid crystal driver of the third embodiment.

### DETAILED DESCRIPTION OF THE INVENTION

Embodiments of a present invention will be description hereinafter with reference to the accompanying drawings.

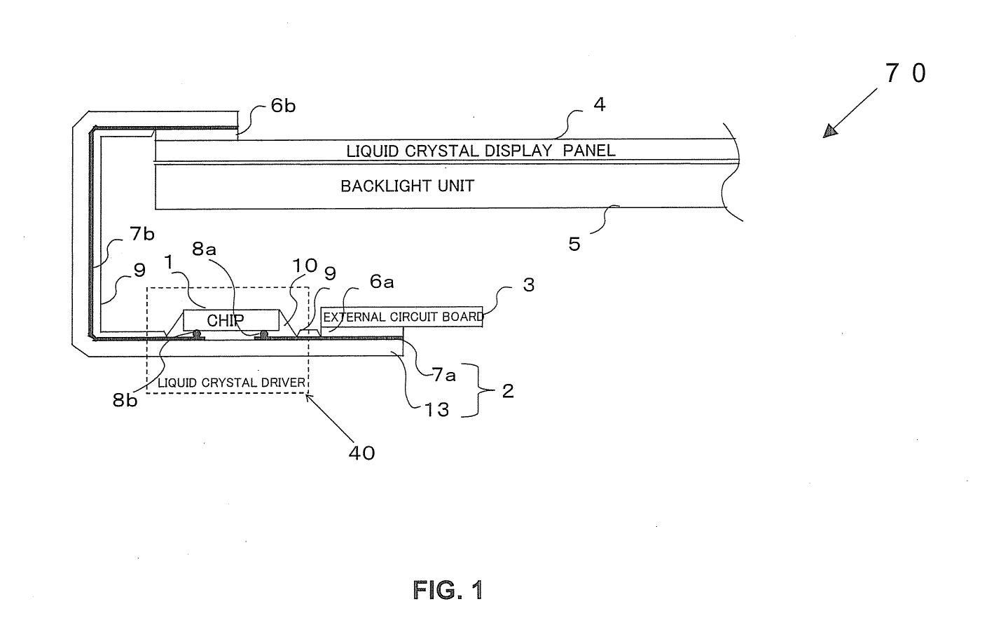

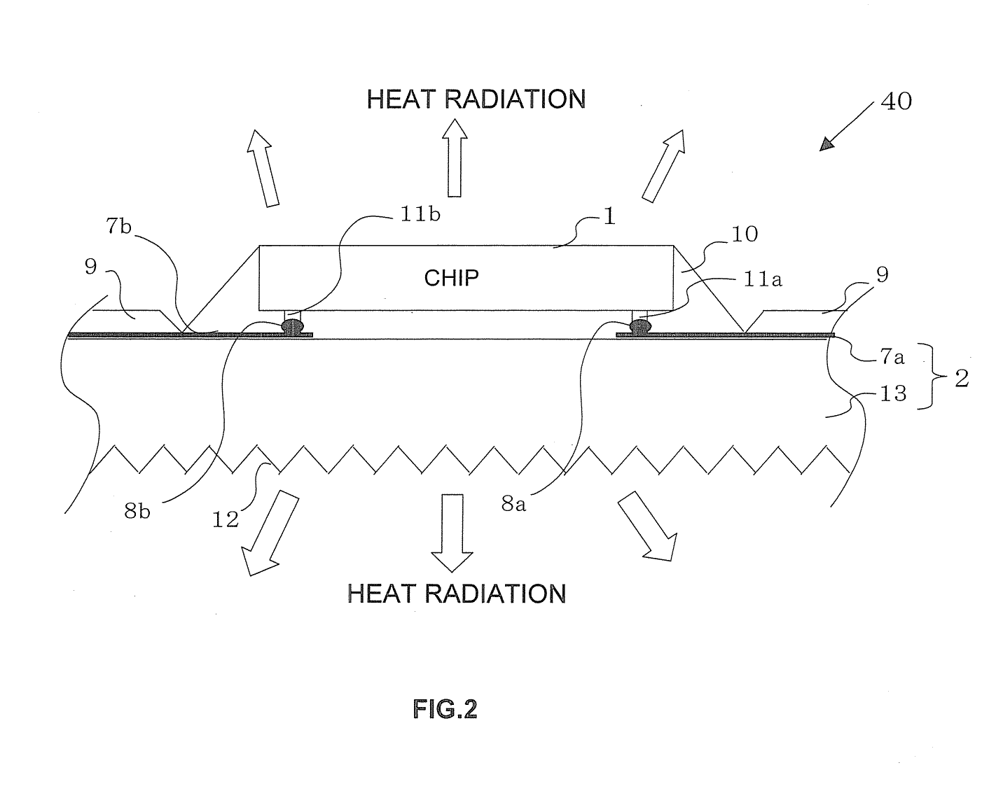

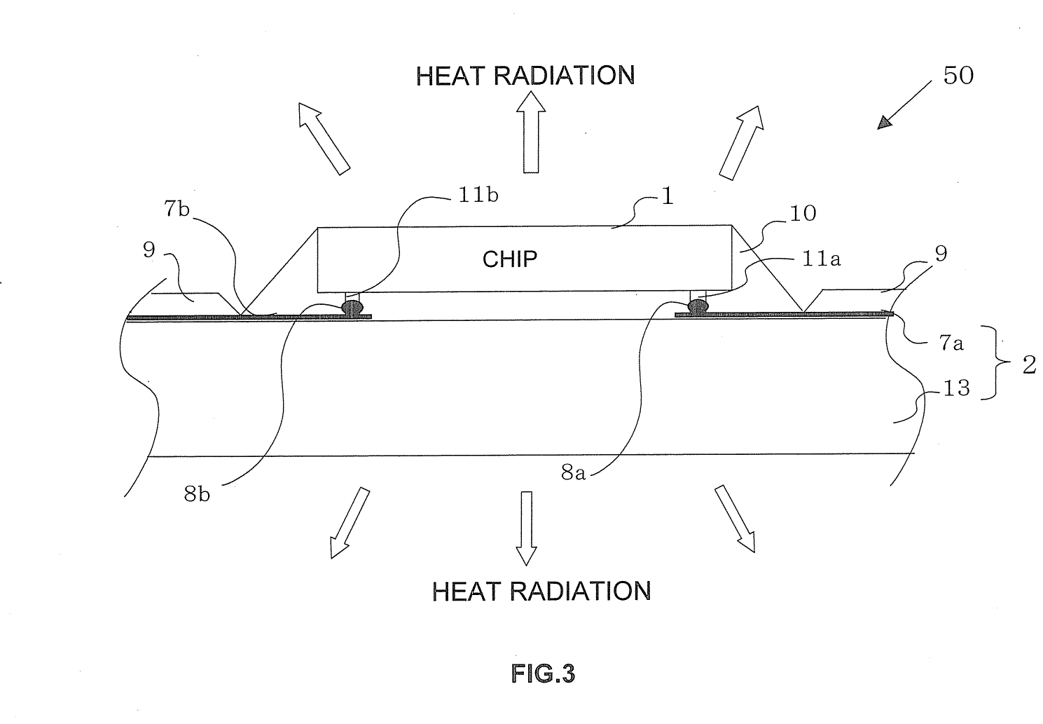

A first embodiment is explained. FIG. 1 is a cross-sectional view showing a liquid crystal display device. FIG. 2 is an enlarged cross-sectional view showing a liquid crystal driver of the first embodiment. FIG. 3 shows a liquid crystal driver of a comparative example. In the embodiment concave-convex portions are formed on an outer surface of a U-shaped flexible substrate for heat radiation of the liquid crystal driver.

As shown in FIG. 1, a liquid crystal display device 70 has a liquid crystal driver 40, a flexible substrate 2, an external circuit board 3, a liquid crystal display panel 4, a backlight unit 5, an adhesive 6a, an adhesive 6b, and a solder resist 9. The liquid crystal display device 70, for example, is applies as a LCD (liquid crystal display) monitor.

The flexible substrate 2 has a two-layer structure of a resin layer and a metal layer. Specifically, the resin layer is preferable to be a polyimide resin with comparatively thick in film thickness. The metal layer is preferable to be leads 7a and 7b with comparatively thin in film thickness.

The flexible substrate 2 is folded to so as to become a U-shaped flexible substrate having an inner surface and an outer surface. The leads 7a and 7b provides the inner surface of the U-shaped flexible substrate 2, while the polyimide resin 13 provides the outer surface of the U-shaped flexible substrate 2.

The flexible substrate 2 may be a flexible substrate of COF system by a casting method. A copper foil pattern is formed by attaching a copper foil to a polyimide resin and etching selectively the copper foil in the casting method.

One end of the lead 7a is electrically connected to the liquid crystal driver 40, and the other end of the lead 7a is connected to the external circuit board 3 via the conductive adhesive 6a.

The external circuit board 3 is bonded with a lower portion of the flexible substrate 2 via the adhesive 6 as shown in FIG. 1 and transmits a digital signal to be used for an image display to the liquid crystal driver 40.

One of end of the lead 7b is electrically connected the liquid crystal driver 40, and the other end of the lead 7b is connected to the liquid crystal display panel 4 via the conductive adhesive 6b. The liquid crystal display panel 4 is bonded with an upper portion of the flexible substrate 2 via the adhesive 6 as shown in the FIG. 1 and receives an analog signal for displaying an image, which is output from the liquid crystal driver 40.

The backlight unit 5 is fixed at the back of the liquid crystal panel 4 via, for example, an optical sheet (not shown). The backlight unit 5 may include a source of light diffusion, a source of luminescence, and a backlight chassis. There is provided the solder resist 9 covering the leads 7a and 7b (except a region of adhesives 6a and 6b), provided at the inner surface of the U-shaped (or folded) flexible substrate 2.

As shown in FIG. 2, the liquid crystal driver 40 includes a liquid crystal driver chip 1. The liquid crystal driver chip 1 is mounted on the inner surface of the flexible substrate 2. Chip terminals 11a and 11b in the liquid crystal driver 40 is on the downside (face down mount). A source driver and a gate driver are needed to drive TFT (Thin Film Transistor) in a LCD. The source driver connects a source of TFT and the gate driver connects a gate of TFT. The liquid crystal driver chip 1 is the source driver. The gate driver is laid in the liquid crystal display panel 4.

The chip terminal 11a of the liquid crystal driver chip 1 is connected to the lead 7a via a needle electrode 8a. The chip terminal 11b of the liquid crystal driver chip 1 is connected to the lead 7b via a needle electrode 8b. Needle electrodes 8a and 8b are preferably gold bump. A resin 10 is filled up the side and bottom of the liquid crystal driver chip 1 as an underfill material. A resin 10, for example, is an epoxy resin.

Concave-convex portions 12 are formed on an outer surface of a polyimide resin 13 of the flexile substrate 2 (at the lower side of FIG. 2). The concave-convex portions 12 also may be preferably formed on the entire outer surface of the polyimide resin 13 of the flexible substrate 2 (including at the top side and left side of the U-shaped flexible substrate 2 in FIG. 1). The concave-convex portions 12 may be formed on the outer surface of the polyimide resin 13 before the copper foil is attached. For example, before using the casting method. It is preferable that pitch of concave-convex portions 12 is 7 μm and height is 400 μm.

Since the concave-convex portions 12 are formed on the outer surface of the polyimide resin 13, heat radiation areas of the flexible substrate 2 increase and heat radiation of the liquid crystal driver chip 1 can be transferred outside of the flexible substrate 2 even when a thermal conductivity of the polyimide resin 13 is comparatively small. Therefore heat radiation efficiency will is greatly improved in the outer surface of the flexible substrate 2.

Since the flexible substrate 2 is U-shaped, sources of heat such as the liquid crystal driver 40, the backlight unit 5 and the liquid crystal display panel 4 are also provided on the top of the U shaped flexible substrate 2. Therefore an inner space of a U-shape where the inner surface of the flexible substrate 2 is facing, is easily filled with heat even when a thermal conductivity (151 W/mk) of a silicon substrate of the liquid crystal driver chip 1 is comparatively large. As the result, the inner surface of the flexible substrate 2, when folded, is inefficient in heat radiation.

As shown in FIG. 3, in a liquid crystal driver 50 of a comparative example, an outer surface of a polyimide resin 13 is flat and has no concave-convex portions. Therefore heat radiation areas are small and heat radiation of the liquid crystal driver chip 1 cannot be transferred outside the flexible substrate 2. Heat radiation efficiency of the outer surface of the flexible substrate 2 of the comparative example is less inefficient than that of the embodiment above.

The liquid crystal driver 50 of the comparative example has the same structure of the liquid crystal driver 40 except that the outer surface of the polyimide resin 13 is flat.

As described above, in the embodiment, the liquid crystal display device 70 has the liquid crystal driver 40. The liquid crystal driver 40, shown in dotted line in FIG. 1, has the flexible substrate 2 and the liquid crystal driver chip 1. The flexible substrate 2 includes the polyimide resin 13 and lead. The flexible substrate 2 is folded and U-shaped, having the concave-convex portions 12. The liquid crystal driver chip 1 is provided on the inner surface of the flexible substrate 2, being connected with the flexible substrate 2 via the needle electrode. The top and sides of the liquid crystal driver chip 1 sealed by the resin 10. By the concave-convex portions 12, a substantial surface area of the outer surface of the flexible substrate 2 is lager.

Heat generated by the liquid crystal driver chip 1 (on the inner surface the flexible substrate 2) can quickly radiated to outside from the outer surface of the flexible substrate 2. Thus, heat radiation efficiency of the liquid crystal driver 40 is greatly improved.

Instead of the COF method of the flexible substrate using the casting method, a coat, a deposition, a sputter method, a laminate method may be used. In the embodiment the liquid crystal display device 70 applies to the LCD (liquid crystal display) monitor. Instead, it may apply to a LCD-TV, a display device for a mobile phone, a display device for a PDA, a display device for a cam decoder. The concave-convex portions 12 are formed on the outer surface of the flexible substrate 2 in the first embodiment. The concave-convex portions 12 may be formed also on the inner surface of the flexible substrate 2. In this case, it is better that the concave-convex portions 12 are formed on an area wherein leads 7a and 7b are not provided.

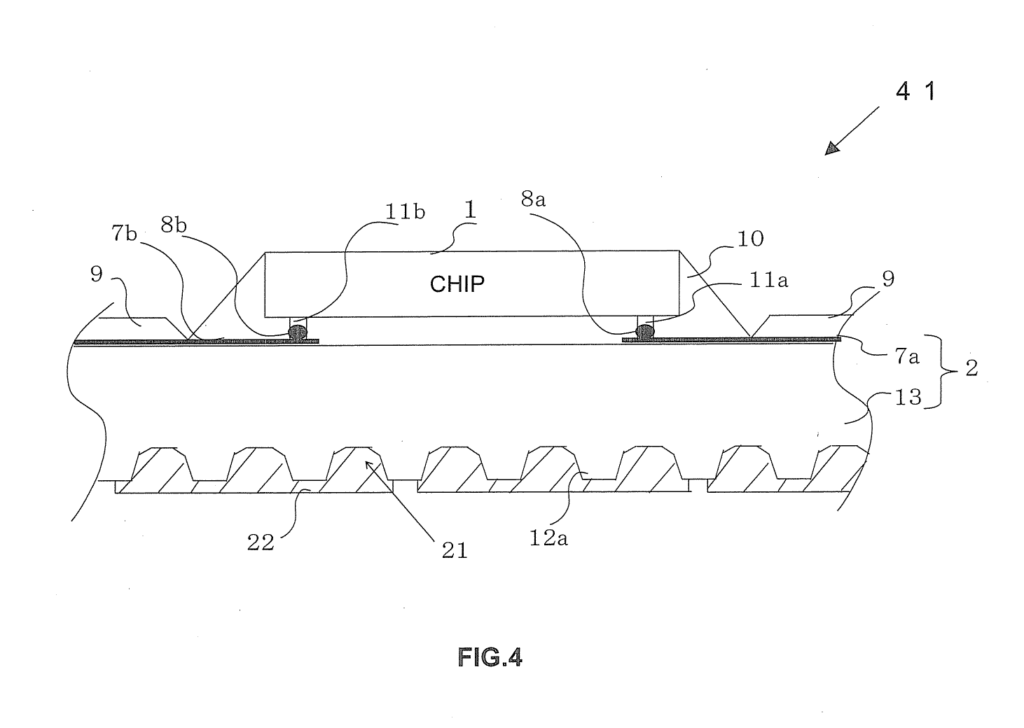

A second embodiment is explained. FIG. 4 is a cross-sectional view showing a liquid crystal driver. In the embodiment, concave-convex portions are formed on a flexible substrate and concave portions are covered with materials of heat radiation for heat radiation of a liquid crystal driver.

In the embodiment, the same reference numbers are those of the first embodiment designated to the same portions.

As shown in FIG. 4, a liquid crystal driver 41 includes a liquid crystal driver chip 1. The liquid crystal driver chip 1 is mounted on an inner surface (upper portion of FIG. 4) of a flexible substrate 2. Chip terminals 11a and 11b in the liquid crystal driver 41 is on the downside (face down mount). Concave convexportions 12a are formed on an outer surface of a polyimide resin 13 of the flexible substrate 2 (at the lower side of FIG. 4). Materials of heat radiation 22 are covered with the convex portions 21 of the concave-convex portions 12a. The concave-convex portions 12a and the materials of heat radiation 22 also may be formed on the entire outer surface of the flexible substrate 2 on an area wherein the liquid crystal driver chip 1 are not provided including at the top side and left side of flexible substrate 2). It is preferable that pitch of concave-convex portions 12 is 7 μm and size of concave portions is 400 μm.

It's preferred that the material of heat radiation 22 may be used an insulating material which thermal conductivity is higher than that of a polyimide resin 13. The material of heat radiation of the embodiment is used an aluminum nitride with thermal conductivity of 170-200 W/mk. Instead, it may be used a silicon carbide of 55-150 W/mk, a silicon nitride of 20-150 W/mk, a boron nitride of 50-60 W/mk, an alumina of 29-36 W/mk.

It's preferred that a method of attaching the material of heat radiation 22 with the outer surface of the flexible substrate 2 is that an aluminum nitride may be sintered and be attached with the concave-convex portions 12a.

By materials of heat radiation 22, heat radiation of the liquid crystal driver chip 1 can be quickly transferred outside of the flexible substrate 2. Therefore heat radiation efficiency is greatly improved in the outer surface of the flexible substrate.

As described above, in the embodiment, the liquid crystal driver 41 has the flexible substrate 2, materials of heat radiation 22, and the liquid crystal driver chip 1. The flexible substrate 2 is folded and U-shaped, having the concave-convex portions 12a on the outer surface of the flexible substrate 2. Materials of heat radiation 22 are covered with the convex portions 21 of the concave-convex portions 12a. The liquid crystal driver chip 1 is provided on the inner surface of the flexible substrate 2, being connected with the flexible substrate 2 via needle electrodes. The top and sides of the liquid crystal driver chip 1 is sealed by a resin 10.

Heat radiation of the liquid crystal driver chip 1 can be quickly transferred outside of the flexible substrate 2. Therefore heat radiation efficiency is greatly improved in the liquid crystal driver 41.

The concave portions 21 are formed on the outer surface of the flexible substrate 2 in the second embodiment. The concave portions 21 may be formed also on the inner surface of the flexible substrate 2. In this case, it is better that the concave portions 21 are formed on an area wherein leads 7a and 7b are not provided.

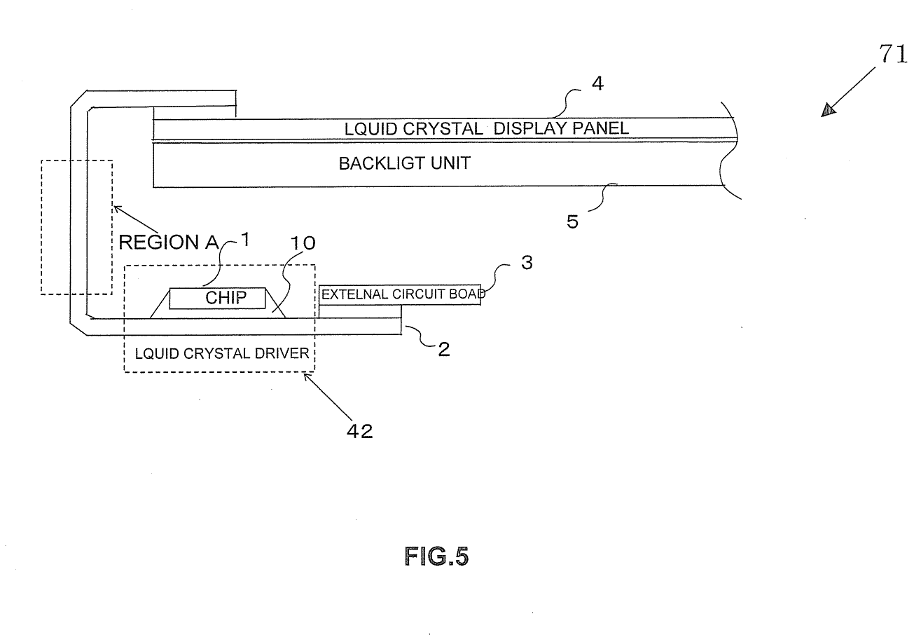

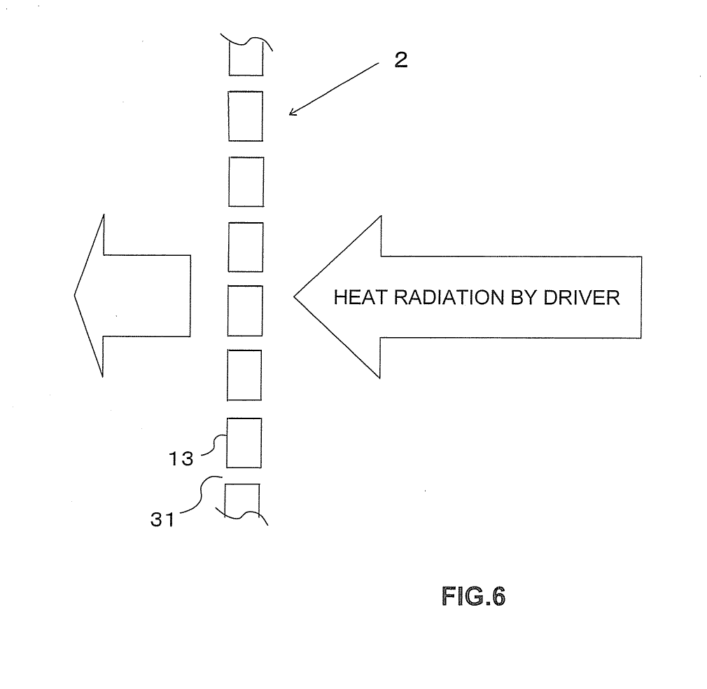

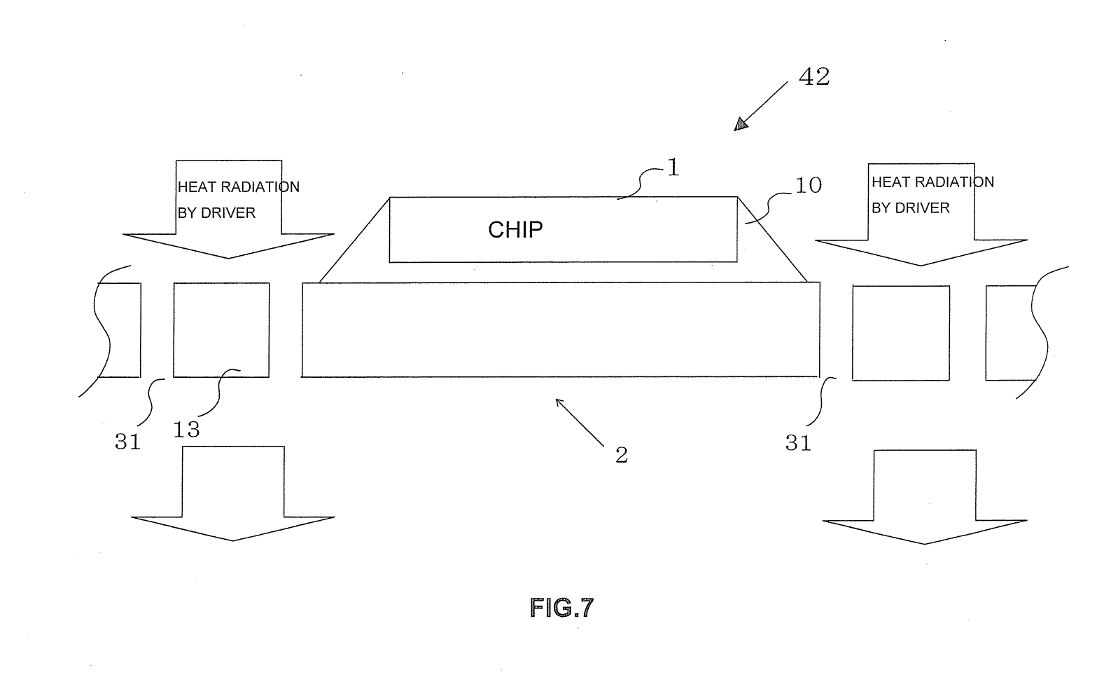

A third embodiment is explained. FIG. 5 is a cross-sectional view showing a liquid crystal display device. FIG. 6 is an enlarged cross-sectional view showing a region A of FIG. 5. FIG. 7 is an enlarged cross-sectional view showing a liquid crystal driver of the third embodiment. In the embodiment, through holes are provided in a flexible substrate for heat radiation.

As showed in FIG. 5, a liquid crystal display device 71 has a flexible substrate 2, an external circuit board 3, a liquid crystal display panel 4 and a backlight unit 5. The liquid crystal display device 71, for example, is applies as a LCD (liquid crystal display) monitor. Although the flexible substrate 2 is folded and has a lead in its inner surface, FIG. 5 shows the cross-sectional view of a portion of the flexible substrate 2 where the lead is not provided.

As shown in FIG. 6, the flexible substrate 2 is U-shaped. An outer surface of the flexible substrate 2 has a polyimide resin 13. Through holes 31 are provided in a portion of a bottom of the flexible substrate 2 which is not provided the lead (i.e. the left side of FIG. 5). Through holes 31 have intervals each other. By through holes 31 heat radiation of the liquid crystal driver chip 1, back light unit 5, and liquid crystal display 4 can be transferred outside the U-shaped flexible substrate 2. It is preferable that pitch is height of through holes 31 is about 400 μm

As shown in FIG. 7, the liquid crystal driver 42 includes the liquid crystal driver chip 1. Through holes 31 which have intervals each other are provided in the polyimide resin 13 except an area sealed by a resin 10. By through holes 31 heat radiation of the liquid crystal driver chip 1, back light unit 5, and liquid crystal display 4 can be transferred outside the U-shaped flexible substrate 2.

As described above, in the embodiment, the liquid crystal display 71 has the liquid crystal driver 42, the flexible substrate 2, the external circuit board 3, the liquid crystal display panel 4, and the backlight unit 5. The liquid crystal driver 42, shown in dotted line in FIG. 5, has the flexible substrate 2 and the liquid crystal driver chip 1. The flexible substrate 2 includes the polyimide resin 13 and lead. The flexible substrate 2 is folded and U-shaped. The liquid crystal driver chip 1 is provided on the inner surface of the flexible substrate 2, being connected with the flexible substrate 2 via the needle electrode. The top and sides of the liquid crystal driver chip 1 sealed by the resin 10. Through holes 31 which have intervals each other are provided in the polyimide resin 13 except an area sealed by a resin 10.

Heat generated by the liquid crystal driver chip 1 (on the inner surface the flexible substrate 2) can quickly radiated to outside from the outer surface of the flexible substrate 2. Thus, heat radiation efficiency of the liquid crystal driver 42 is greatly improved.

Other embodiments or modifications of the present invention will be apparent to those skilled in the art from consideration of the specification and practice of the invention disclosed herein. It is intended that the specification and example embodiments be considered as exemplary only, with a true scope and spirit of the invention being indicated by the following.

In the embodiments the COF method is used, a TAB (tape automated bonding) method may be used. Although crease performance and ILB pitch of the TAB method is inferior than that of the COF method, heat radiation may be improved by the TAB method. Alternatively, materials of heat radiation having high thermal conductivity may be implanted into the through holes 31 of the flexible substrate 2 in the third embodiment.

What is claimed is:

1. A semiconductor device comprising:
a flexible substrate which can be folded U-shape, an outer surface of the flexible substrate being provided concave-convex portions for heat radiation; and
a semiconductor chip which is mounted on an inner surface of the flexible substrate, the chip being electronically connected with the flexible substrate.

2. A semiconductor device according to claim 1,
wherein the flexible substrate has a two-layer structure of a resin layer and a metal layer.

3. A semiconductor device according to claim 2,
wherein the resin layer contains polyimide and the metal layer has a lead connected with the semiconductor chip.

4. A semiconductor device according to claim 1,
wherein the semiconductor chip is connected with the flexible substrate by a COF method.

5. A semiconductor device according to claim 1,
wherein the semiconductor chip is connected with the flexible substrate by a TAB method.

6. A semiconductor device according to claim 1,
wherein the semiconductor chip is a liquid crystal driver chip.

7. A semiconductor device according to claim 1,
wherein the flexible substrate is connected with the semiconductor chip via needle electrodes which are provided substantially at both ends of the semiconductor chip.

8. A semiconductor device according to claim 7,
wherein each needle electrode is a gold bump.

9. A semiconductor device according to claim 1,
wherein the concave-convex portions are also provided on the inner surface of the flexible substrate.

10. A semiconductor device according to claim 1, further comprising:
materials of heat radiation provided on the concave-convex portions.

11. A semiconductor device according to claim 10,
wherein the materials of heat radiation is at least one selected from a group consisting of an aluminum nitride, a silicon carbide, a silicon nitride, a boron nitride, an alumina.

12. A semiconductor device comprising:
a flexible substrate which can be folded U-shape, the flexible substrate being provided through holes for heat radiation; and
a semiconductor chip which is mounted on an inner surface of the flexible substrate, the chip being electronically connected with the flexible substrate.

13. A semiconductor device according to claim 12,
wherein materials for heat radiation are implanted into the through holes for heat radiation.

14. A semiconductor device according to claim 12,
wherein the flexible substrate has a two-layer structure of a resin layer and a metal layer.

15. A semiconductor device according to claim 14,
wherein the resin layer contains polyimide and the metal has a lead connected with the semiconductor chip.

16. A semiconductor device according to claim 12,
wherein the semiconductor chip is connected with the flexible substrate by a COF method.

17. A semiconductor device according to claim 12,
wherein the semiconductor chip is connected with the flexible substrate by a TAB method.

18. A semiconductor device according to claim 12,
wherein the semiconductor chip is a liquid crystal driver chip.

19. A semiconductor device according to claim 12,
wherein the flexible substrate is connected with the semiconductor chip via needle electrodes which are provided substantially at both ends of the semiconductor chip.

20. A semiconductor device according to claim 19,
wherein each needle electrode is a gold bump.
